(19) United States
(12) Patent Application Publication
(10) Pub. No.: US 2026/0138204 A1
(43) Pub. Date: May 21, 2026

(54) AUTOMATIC BONDING TOOL REPLACEMENT APPARATUS AND METHOD

(71) Applicant: ASMPT Singapore Pte. Ltd., Singapore (SG)

(72) Inventors: Yue ZHANG, Singapore (SG); Keng Yew SONG, Singapore (SG); Feng You ZHU, Chengdu City (CN); Sheng Hui JIANG, Chengdu City (CN)

(21) Appl. No.: 19/387,752

(22) Filed: Nov. 13, 2025

(30) Foreign Application Priority Data
Nov. 20, 2024 (CN) 202411666472.0

(51) Int. Cl. B23K 20/00

(52) U.S. Cl. CPC B23K 20/005

(57) ABSTRACT

A bonding tool replacement apparatus for inserting a bonding tool into a retaining hole of a wire bonding apparatus includes a frame, a bonding tool gripper and a compliant structure. The bonding tool gripper is supported by the frame and configured to grip the bonding tool and insert it into the retaining hole at an operation position associated with the wire bonding apparatus by moving the bonding tool toward the retaining hole. The compliant structure flexibly couples the bonding tool gripper to the frame to enable relative movement of the bonding tool gripper with respect to the frame. The compliant structure is configured to deform in response to misalignment between the bonding tool gripped by the bonding tool gripper and the retaining hole during insertion to allow the bonding tool to deflect into alignment with the retaining hole when the bonding tool and the retaining hole are misaligned.

### FIELD OF THE INVENTION

The invention generally relates to a wire bonding system, and in particular to an automatic bonding tool replacement apparatus for installing a bonding tool onto a wire bonding apparatus.

### BACKGROUND

A capillary is typically used as a bonding tool in a wire bonding apparatus. It has a limited lifespan and is prone to damage during the wire bonding process. Consequently, regular or as-needed replacement of the capillary is important for maintaining the efficiency and effectiveness of the wire bonding apparatus. To enhance the efficiency and accuracy of capillary replacement and to avoid the need for manual intervention, various automatic capillary replacement systems and methods have been proposed in the prior art. However, these solutions have their limitations, particularly regarding the success rate and operational efficiency of capillary replacement, which remain unable to meet the demands of high-volume production.

Furthermore, due to space constraints in a wire bonding apparatus, existing capillary replacement devices are typically positioned at an operation position beneath a wire bonding kit used in association with the wire bonding apparatus and the entire replacement process is carried out beneath the wire bonding kit. This wire bonding kit may include a copper wire bonding kit (“Cu Kit”) used for preventing the oxidation of copper wire utilized during copper wire bonding, or for other purposes during other types of wire bonding. This structural arrangement restricts the space available for a window clamp and top plate of the wire bonding apparatus, which in turn limits a range of widths of the lead frame that the wire bonding apparatus is capable of bonding.

It would therefore be beneficial to provide an improved bonding tool replacement apparatus for a wire bonding apparatus.

### SUMMARY OF THE INVENTION

It is thus an object of the invention to seek to provide an automatic bonding tool replacement apparatus which overcomes at least one of the aforementioned problems of the prior art.

According to a first aspect of the present invention, there is provided a bonding tool replacement apparatus for inserting a bonding tool into a retaining hole of a bonding tool retainer of a wire bonding apparatus. The bonding tool replacement apparatus includes a frame, a bonding tool gripper and a compliant structure. The bonding tool gripper is supported by the frame and configured to grip the bonding tool and to insert the bonding tool into the retaining hole at an operation position associated with the wire bonding apparatus by moving the bonding tool toward the retaining hole. The compliant structure flexibly couples the bonding tool gripper to the frame to enable relative movement of the bonding tool gripper with respect to the frame. In use, the compliant structure is configured to deform in response to misalignment between the bonding tool gripped by the bonding tool gripper and the retaining hole during insertion to allow the bonding tool to deflect into alignment with the retaining hole during insertion when the bonding tool and the retaining hole are misaligned.

In some embodiments, the bonding tool gripper is further configured to grip a used bonding tool retained by the bonding tool retainer of the wire bonding apparatus at the operation position and to remove it from the wire bonding apparatus.

In some embodiments, the compliant structure includes a set of resilient components that are arranged to flex or bend in response to a force caused by a positional or angular offset of the bonding tool relative to the retaining hole during insertion so as to allow the bonding tool to deflect into alignment with the retaining hole while the bonding tool is being inserted into the retaining hole. The positional or angular offset may be determined based on an offset between a central axis of the bonding tool and a central axis of the retaining hole.

In some embodiments, the compliant structure comprises a first pair of leaf springs arranged to extend along first parallel planes that are parallel to an extension direction of the bonding tool gripper. In use, the first pair of leaf springs are deformable or deflectable in a first direction substantially perpendicular to the extension direction of the bonding tool gripper in response to a force along the first direction caused by the misalignment.

In some embodiments, the compliant structure may further include a second pair of leaf springs arranged to extend along second parallel planes that are orthogonal with the extension direction of the bonding tool gripper. In use, the second pair of leaf springs may be deformed or deflected in a second direction substantially parallel to the extension direction of the bonding tool gripper in response to a force along the second direction caused by the misalignment.

In some embodiments, the bonding tool replacement apparatus further includes a position indicator fixedly located with respect to the bonding tool gripper for determining a position of the bonding tool gripper with a vision system. The position indicator may be located on an arm coupled to the bonding tool gripper such that the position indicator is viewable by a camera when the bonding tool replacement apparatus is located at the operation position associated with the wire bonding apparatus. The camera may be included in the wire bonding apparatus. When the bonding tool replacement apparatus is used to insert a new bonding tool into the retaining hole, the position indicator is used to determine the position of the bonding tool gripper, in turn determining the position of the new bonding tool gripped by the bonding tool gripper, so that the bonding tool retainer of the wire bonding apparatus is positioned above the bonding tool gripper to allow the insertion of the bonding tool. When the bonding tool replacement apparatus is used to remove a used bonding tool from the wire bonding apparatus, the position indicator is used to determine the position of the bonding tool gripper so that the bonding tool retainer is moved to allow the bonding tool gripper to grip the used bonding tool.

In some embodiments, the bonding tool replacement apparatus further includes a holding structure connected to the bonding tool gripper at a position directly below the bonding tool gripper, wherein the holding structure is configured to support or hold a tip portion of the bonding tool during the insertion of the bonding tool into the retaining hole.

In some embodiments, the bonding tool gripper is further configured to release the bonding tool to form a guide hole for inserting the bonding tool into the retaining hole when the tip portion of the bonding tool is held by the holding structure. The holding structure is configured to maintain position and orientation of the bonding tool after the bonding tool is not being gripped by the bonding tool gripper.

In some embodiments, the frame of the bonding tool replacement apparatus further includes a first connecting component configured to detachably connect the frame to a first docking station of the wire bonding apparatus. The first connecting component is provided to stabilize the frame when the bonding tool gripper is inserting the bonding tool into the retaining hole. In some embodiments, the first connecting component may include a plurality of first locking elements located on the frame, shaped and sized to connect detachably with a plurality of second locking elements located on the first docking station of the wire bonding apparatus.

In some embodiments, the bonding tool replacement apparatus may further include a vision system configured to detect a fiducial mark located on the first docking station for aligning the frame with the first docking station prior to engagement between the first docking station and the frame.

In some embodiments, the bonding tool replacement apparatus may further include a movable manipulator operative to transfer the bonding tool gripper between a standby position and the operation position associated with the wire bonding apparatus. The vision system may be installed on the movable manipulator.

In some embodiments, the movable manipulator may include an automated vehicle, and a robot arm movably installed on the automated vehicle. The frame of the bonding tool replacement apparatus is installed on the robot arm.

In some embodiments, the bonding tool replacement apparatus further includes a bonding tool container configured to hold at least one bonding tool, wherein the robot arm is further configured and operative to move the bonding tool gripper between the operation position and the bonding tool container, and wherein the bonding tool gripper is configured to pick up the bonding tool from the container or return a used bonding tool to the container. In some embodiments, the bonding tool container is carried by the automated vehicle.

In some embodiments, the bonding tool replacement apparatus further includes a second connecting component configured to detachably connect the frame to a second docking station for stabilizing the frame when the bonding tool gripper is picking up the bonding tool from the container or returning the used bonding tool to the container.

In some embodiments, the second connecting component may include a plurality of third locking elements located on the frame, shaped and sized to connect detachably with a plurality of fourth locking elements located on the second docking station of the wire bonding apparatus.

In some embodiments, the vision system of the bonding tool replacement apparatus may be further configured to detect a fiducial mark located on the second docking station for aligning the frame with the second docking station prior to engagement between the second docking station and the frame.

The first and second connecting components may either be the same component or two separate components. If they are separate, they may share the same structure.

If they are the same component, the first and third locking elements will be the same set of locking elements, and the plurality of fourth locking elements on the second docking station will share the same structure as the plurality of second locking elements on the first docking station.

In some embodiments, the movable manipulator is configured to transfer the bonding tool gripper to the operation position associated with the wire bonding apparatus upon receipt of a bonding tool replacement signal associated with the wire bonding apparatus.

In some embodiments, the movable manipulator is communicably connected to a server and is configured to receive the bonding tool replacement signal from the server, wherein the sever is configured to generate and send the bonding tool replacement signal to the movable manipulator according to preset conditions. The preset conditions may include preset time period, and/or preset usage parameter thresholds related to bonding tools, e.g., the number of uses. The server may be configured to send the bonding tool replacement signal to the movable manipulator when the usage data of the bonding tool obtained from the wire bonding apparatus exceeds a preset usage parameter threshold, or send the signal regularly based on a preset time period, e.g., 3 months.

In some embodiments, when the bonding tool replacement apparatus is in use, the bonding tool gripper is positioned between the bonding tool retainer and a copper wire bonding kit used in association with the wire bonding apparatus.

In some embodiments, the bonding tool gripper may be configured to grip the bonding tool such that a central axis of the bonding tool is substantially aligned with that of the retaining hole when the bonding tool retainer is raised and positioned at an oblique angle relative to a horizontal plane, and the bonding tool gripper is further configured to move along a direction substantially parallel to the central axis of the retaining hole so as to insert the bonding tool into the retaining hole.

According to a second aspect of the present invention, there is provided a wire bonding system comprising a wire bonding apparatus including a bonding tool retainer having a retaining hole and a bonding tool replacement apparatus for inserting a bonding tool into the retaining hole. The bonding tool replacement apparatus includes a frame, a bonding tool gripper and a compliant structure. The bonding tool gripper is supported by the frame and is configured to grip the bonding tool and to insert the bonding tool into the retaining hole at an operation position associated with the wire bonding apparatus by moving the bonding tool toward the retaining hole. The compliant structure is configured to flexibly couple the bonding tool gripper to the frame to enable relative movement of the bonding tool gripper with respect to the frame. The compliant structure is configured to deform in response to misalignment between the bonding tool gripped by the bonding tool gripper and the retaining hole during insertion to allow the bonding tool to deflect into alignment with the retaining hole during insertion when the bonding tool and the retaining hole are misaligned.

In some embodiments, the wire bonding system may include a plurality of wire bonding apparatus, each wire bonding apparatus including a bonding tool retainer having a retaining hole. The bonding tool replacement apparatus is further configured to receive a bonding tool replacement signal associated with a first wire bonding apparatus among the plurality of wire bonding apparatus in the wire bonding system and to insert a bonding tool into the retaining hole of the first wire bonding apparatus.

According to a third aspect of the present invention, there is provided a method for inserting a bonding tool into a retaining hole of a bonding tool retainer of a wire bonding apparatus. The method includes the following steps: positioning a bonding tool replacement apparatus is positioned at an operation position associated with the wire bonding apparatus. The bonding tool replacement apparatus is operated to grip the bonding tool and insert it into the retaining hole by moving the bonding tool toward or relative to the retaining hole. During the insertion of the bonding tool, the compliant structure is deformable in response to a misalignment between the bonding tool and the retaining hole to allow the bonding tool to deflect into alignment with the retaining hole during insertion when the bonding tool and retaining hole are misaligned.

In some embodiments, the bonding tool replacement apparatus is positioned at the operation position upon receipt of a bonding tool replacement signal associated with the wire bonding apparatus. The bonding tool replacement signal may be generated and sent by the wire bonding apparatus, or a server communicably connected to the wire bonding apparatus.

The method may further include a step of gripping a used bonding tool at the operation position and removing the used bonding tool from the retaining hole with the bonding tool gripper.

The bonding tool replacement signal may be generated by the wire bonding apparatus or a server communicably, which is connected to the wire bonding apparatus and the bonding tool replacement apparatus, based on preset conditions.

These and other features, aspects, and advantages will be better understood with regard to the description section, appended claims, and accompanying drawings.

### BRIEF DESCRIPTION OF THE DRAWINGS

Embodiments of the present invention will now be described, by way of example only, with reference to the accompanying drawings, in which:

FIG. 1A and FIG. 1B respectively show perspective and side views of a bonding tool replacement device before a bonding tool gripped by the bonding tool replacement device is installed on the wire bonding apparatus according to some embodiments of the invention; FIG. 1C and FIG. 1D respectively show perspective and side views of the bonding tool replacement device when it is installing the bonding tool onto the wire bonding apparatus according to some embodiments of the invention;

FIG. 2A and FIG. 2B respectively show top and perspective views of a compliant structure according to one embodiment of the invention; FIG. 2C illustrates the bending of a first pair of leaf springs included in the compliant structure in response to a force F exerted perpendicular to their extension direction.

FIG. 3A and FIG. 3B illustrate a compliant structure according to another embodiment of the invention.

FIG. 4A and FIG. 4B respectively show perspective and side views of the bonding tool replacement device that further includes a holding structure according to another embodiment of the invention;

FIG. 5 is a schematic diagram illustrating a wire bonding system including a plurality of wire bonding apparatus and a bonding tool replacement apparatus according to some embodiments of the invention;

FIG. 6A to FIG. 6E illustrate some steps of the bonding tool replacement method for a wire bonding apparatus using the bonding tool replacement apparatus according to some embodiments of the invention.

In the drawings, like parts are denoted by like reference numerals.

### DETAILED DESCRIPTION OF THE PREFERRED EMBODIMENTS OF THE INVENTION

Before discussing embodiments of the invention in any more detail, first an overview will be provided. To improve the precision and efficiency of installing a bonding tool onto a wire bonding apparatus, an automatic bonding tool replacement apparatus is provided. According to some embodiments of the invention, the bonding tool replacement apparatus includes a bonding tool replacement device that includes a frame, a bonding tool gripper and a compliant structure flexibly coupling the bonding tool gripper to the frame to enable relative movement of the bonding tool gripper with respect to the frame. The compliant structure is provided to automatically absorb and compensate for a misalignment between a bonding tool gripped by the bonding tool gripper and a retaining hole of a bonding tool retainer of the wire bonding apparatus during the insertion of the bonding tool into the retaining hole. The bonding tool replacement apparatus may further include a movable manipulator configured to support the bonding tool replacement device and transfer it between a standby position and an operation position. The operation position is associated with the wire bonding apparatus. If the wire bonding system includes a plurality of wire bonding apparatus, the bonding tool replacement device may be transferred between its standby position and an operation position corresponding to or associated with each wire bonding apparatus.

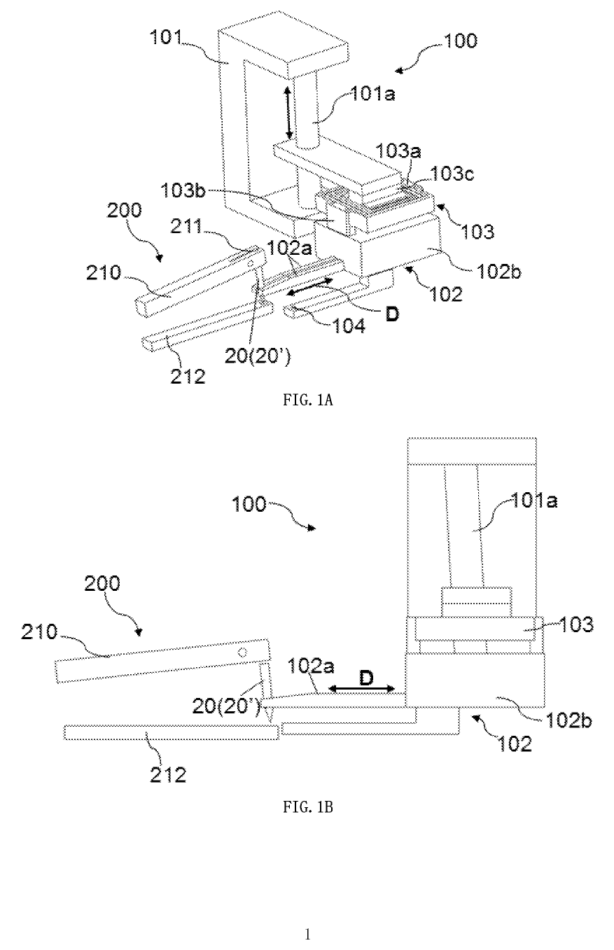

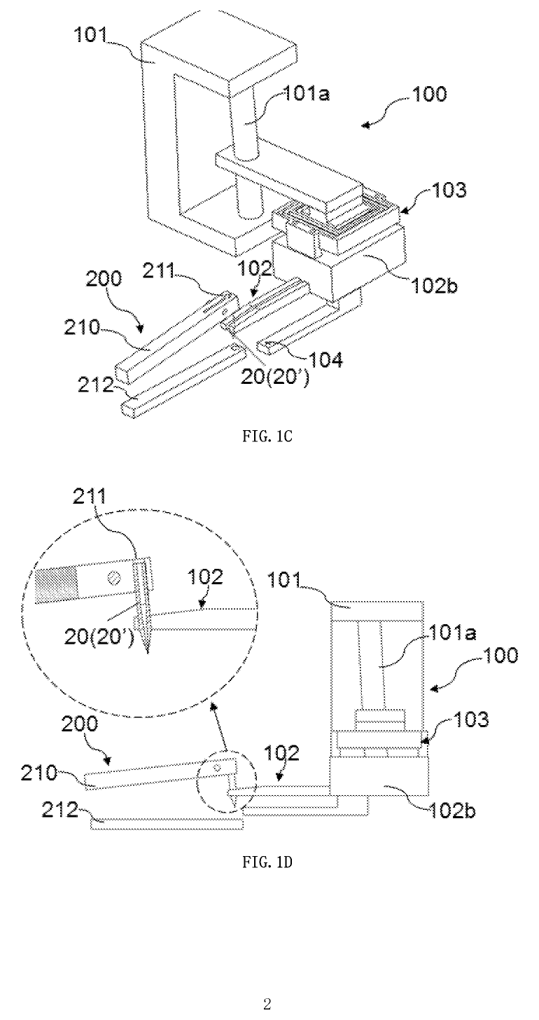

FIG. 1A and FIG. 1B respectively show perspective and side views of a bonding tool replacement device 100 before a bonding tool 20 gripped by the bonding tool replacement device 100 is installed on the wire bonding apparatus 200 according to some embodiments of the invention. FIG. 1C and FIG. 1D respectively show perspective and side views of the bonding tool replacement device 100 when it is installing the bonding tool 20 on the wire bonding apparatus 200 according to some embodiments of the invention.

Referring to FIG. 1A to FIG. 1D, the wire bonding apparatus 200 includes a bonding tool retainer 210 having a retaining hole 211. The bonding tool replacement device 100 is used to insert the bonding tool 20 into the retaining hole 211 of the bonding tool retainer 210. The retaining hole 211 may include a chamfered receiving portion, shaped and sized to facilitate the insertion of the bonding tool 20.

The bonding tool replacement device 100 includes a frame 101, a bonding tool gripper 102 and a compliant structure 103. The bonding tool gripper 102 is supported by the frame 101 and is operative to grip the bonding tool 20. To insert the bonding tool 20 gripped by the bonding tool gripper 102 into the retaining hole 211, the bonding tool gripper 102 is positioned at an operation position associated with the wire bonding apparatus 200. As shown in FIG. 1A to 1D, the operation position is between the bonding tool retainer 210 and a Cu Kit 212 of the wire bonding apparatus 200. The compliant structure 103 is configured to flexibly couple the bonding tool gripper 102 to the frame 101, allowing for movement of the bonding tool gripper 102 relative to the frame 101 along a plane of the compliant structure 103 when a force is applied to the compliant structure 103 through the bonding tool gripper 102. This arrangement enables the compliant structure 103 to deform or deflect if there is any misalignment between the bonding tool 20 gripped by the bonding tool gripper and the retaining hole 211 during insertion. As a result, the bonding tool 20 is able to deflect into alignment with the retaining hole 211 during insertion to compensate for any misalignment.

The frame 101 includes a sliding track or sliding column 101a. The compliant structure 103 is movably coupled to the sliding track or sliding column 101a. Thus, the bonding tool gripper 102, together with the complaint structure 103, is movable along the sliding track or sliding column 101a. This allows the bonding tool gripper 102 to move toward or away from the retaining hole 211 during the bonding tool replacement process. Specifically, during the insertion of the bonding tool 20 into the retaining hole 211, the bonding tool gripper 102 is operated to move toward the retaining hole 211.

The bonding tool gripper 102 includes a pair of clamping fingers 102a for gripping the bonding tool 20 to be inserted into the retaining hole 211 of the bonding tool retainer 210. In some embodiments, the bonding tool 20 is in the form of a capillary. The pair of clamping fingers 102a include recesses that are configured to form a receiving hole for releasably gripping the bonding tool 20. The bonding tool gripper 102 further includes a first actuator 102b operative to move the pair of clamping fingers 102a from an open position towards a clamped position to grip the bonding tool 20, and vice versa, from the clamped position back to the open position to release the gripped bonding tool 20. The bonding tool gripper 102 may further include a second actuator (not shown) operative to actuate the bonding tool gripper 102 to move along a direction parallel to the axial direction of the sliding track or sliding column 101a. This structure allows the bonding tool gripper 102 to move the gripped bonding tool 20 toward or away from the retaining hole 211 during the bonding tool replacement process.

The compliant structure 103 may include at least one resilient or flexible element which is arranged to bend or flex in response to positional or angular offsets between a central axis of the bonding tool 20 and a central axis of the retaining hole 211 of the wire bonding apparatus 200. As shown in FIG. 1A, the at least one flexible element may include a plurality of leaf springs. The at least one elastic or flexible element is configured and arranged to be deformable or deflectable in response to a force caused by a misalignment between the bonding tool 20 gripped by the bonding tool gripper 102 and the retaining hole 211 during the insertion of the bonding tool 20 into the retaining hole 211 to allow the bonding tool 20 to deflect into alignment with the retaining hole 211 during insertion when the bonding tool 20 and the retaining hole 211 are misaligned. Therefore, the compliant structure 103 is provided to absorb and compensate for the misalignment between the bonding tool 20 and the retaining hole 211 during insertion.

The compliant structure 103 may further include at least one rigid element, which is used to mount the bonding tool gripper 102 to a part of the complaint structure 103, and to couple the complaint structure 103 to the frame 101. As shown in FIG. 1A, the at least one rigid element includes first and second rigid elements 103a and 103b fixed to the bonding tool gripper 102, and a third rigid element 103c coupled to the frame 101. The detailed structure, arrangement, and components of the compliant structure 103 according to some embodiments will be illustrated below.

Referring to FIG. 1A and FIG. 1C, the bonding tool replacement device 100 may further include a position indicator 104 fixedly located with respect to the bonding tool gripper 102 for determining a position of the bonding tool gripper 102 with a vision system. The vision system may be a camera installed on the wire bonding apparatus 200. Specifically, the position indicator 104 has a predetermined positional relationship with the receiving hole of the bonding tool gripper 102, therefore, the position of the receiving hole of the bonding tool gripper 102 can be determined based on the position of the position indicator 104. The position indicator 104 may be located on an arm coupled or attached to the bonding tool gripper 102 such that the position indicator 104 is viewable by the vision system when the bonding tool gripper 102 is positioned at the operation position associated with the wire bonding apparatus 200. The position indicator 104 may be located at a tip portion of the arm. During the replacement process, the position indicator 104 is inspected by the vision system such that the position of the bonding tool gripper 102 is determined based on the position of the position indicator 104. During the installation of the bonding tool 20, the position of the bonding tool 20 held by the bonding tool gripper 102 can be determined based on the position of the receiving hole of the bonding tool gripper 102.

In some embodiments, the bonding tool replacement device 100 may also be configured and operative to grip a used bonding tool retained by the bonding tool retainer 210 and remove it from the bonding tool retainer 210 before the bonding tool replacement apparatus 100 is used to install a new bonding tool (e.g., the bonding tool 20) into the bonding tool retainer 210. Accordingly, FIG. 1C and FIG. 1D also show perspective and side views of the bonding tool replacement apparatus 100 when a used bonding tool 20’ is gripped by the bonding tool gripper 102 before it is removed from the bonding tool retainer 210; and FIG. 1A and FIG. 1B are perspective and side views of the bonding tool replacement device 100 after the used bonding tool 20’ is removed from the bonding tool retainer 210. In actual bonding tool replacement process, the bonding tool replacement device 100 is typically configured to remove a used bonding tool 20’ from the wire bonding apparatus 200 first, and then pick up and grip a new bonding tool 20 from a bonding tool container before inserting it into the retaining hole 211 of the bonding tool retainer 210.

Referring to FIG. 1A to FIG. 1D, during the insertion or removal of the bonding tool 20, 20’, the bonding tool retainer 210 is raised and positioned at an oblique angle relative to a horizontal plane or direction. Accordingly, in use, the bonding tool gripper 102 is configured to grip a bonding tool (a new bonding tool 20 or used bonding tool 20’) such that a central axis of the bonding tool is substantially aligned with that of the retaining hole 211 of the inclined bonding tool retainer 210, and the bonding tool gripper 102 is further configured to move along a direction substantially parallel to the central axis of the retaining hole 211 so as to insert the new bonding tool 20 into the retaining hole 211 or remove the used bonding tool 20’ from the retaining hole 211. Each one of the pair of clamping fingers 102a of the bonding tool gripper 102 has a free end portion that may have an inclined top surface to align with the inclination of the bonding tool retainer 210 when installing the new bonding tool 20 or removing the used bonding tool 20’.

In order to insert the new bonding tool 20 into the retaining hole 211 of the tilted bonding tool retainer 210, the sliding track or sliding column 101a of the frame 101 is also arranged at an oblique angle relative to the vertical direction to allow the bonding tool gripper 102 to move along a direction substantially parallel to the central axis of the retaining hole 211 when the bonding tool retainer 210 is raised and positioned at an oblique angle relative to the horizontal direction.

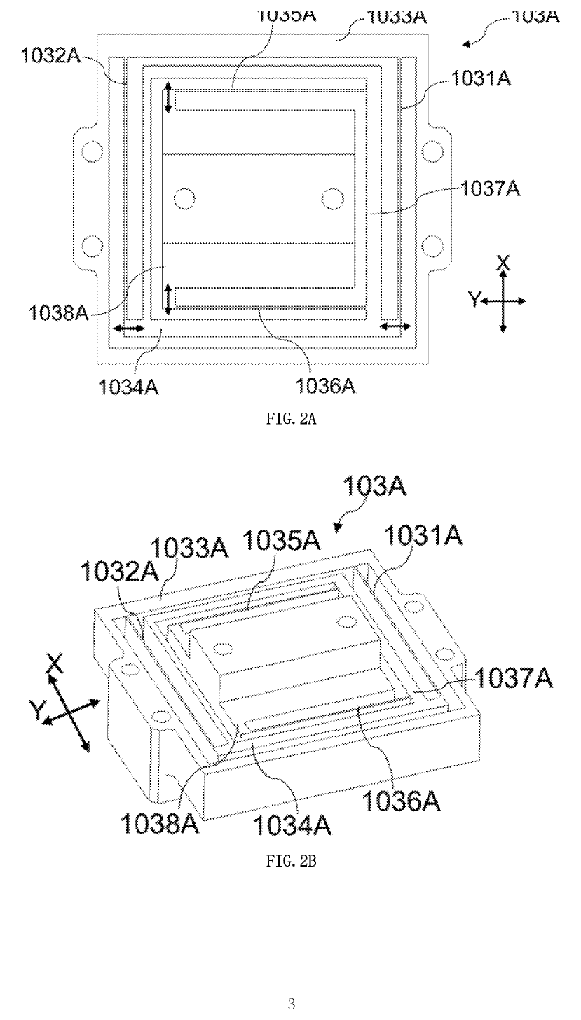

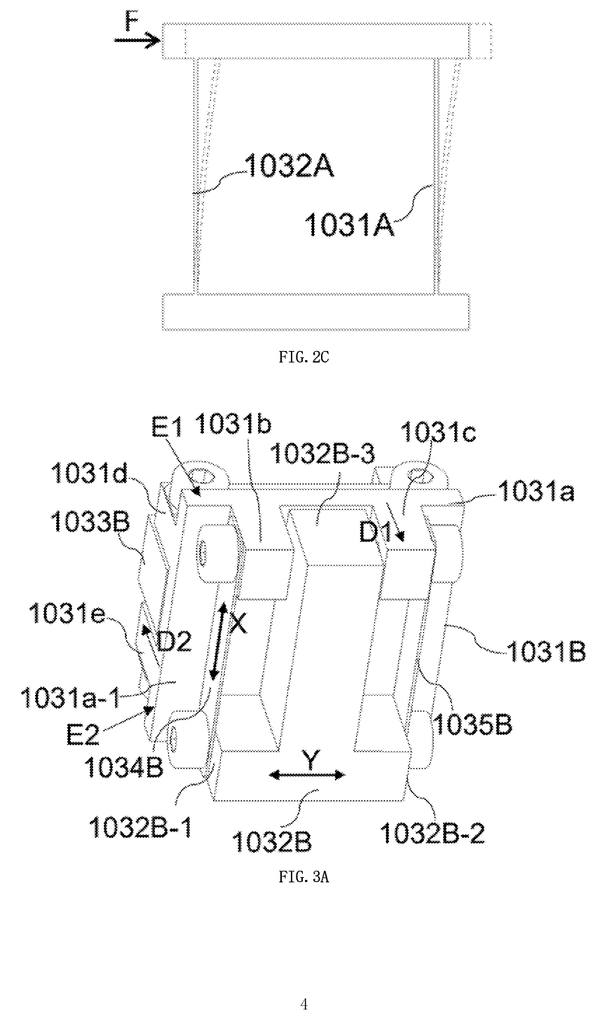

FIG. 2A to FIG. 2C illustrate a compliant structure 103A according to one embodiment of the invention. FIG. 2A and FIG. 2B respectively show a top view and a perspective view of the compliant structure 103A. The compliant structure 103A includes two pairs of leaf springs. A first pair of leaf springs 1031A and 1032A are positioned parallel to each other between two rigid structures 1033A and 1034A. The first pair of leaf springs 1031A and 1032A extend along first parallel planes in a first direction X and are spaced apart in a second direction Y perpendicular to the first direction X. The two rigid structures 1033A and 1034A may include two parallel rigid plates or bars. Similarly, a second pair of leaf springs 1035A and 1036A are positioned parallel to each other between two rigid structures 1037A and 1038A. The second pair of leaf springs 1035A and 1036A extend along second parallel planes in the second direction Y and are spaced apart along the first direction X. The two rigid structures 1037A and 1038A may include two parallel rigid plates or bars. In this embodiment, all of the leaf springs 1031A ,1032A, 1035A and 1036A are arranged on the same plane. FIG. 2C illustrates the bending of the first pair of leaf springs 1031A and 1032A in response to a force F exerted perpendicular to their extension direction. In this embodiment, the second direction Y is parallel to an extension direction D of the bonding tool gripper 102 as shown in FIG. 1A and FIG. 1B.

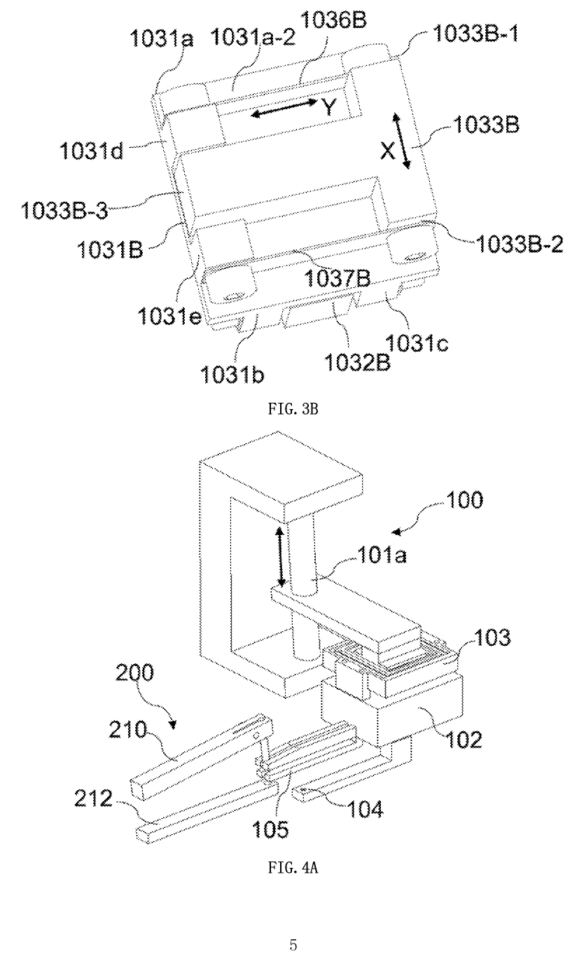

FIG. 3A and FIG. 3B illustrate a compliant structure 103B according to another embodiment of the invention. The compliant structure 103B includes a four-legged part 1031B, two T-shaped parts 1032B and 1033B and two pairs of leaf springs 1034B, 1035B, 1036B and 1037B. The compliant structure 103 forms a double-layer flexible structure.

The four-legged part 1031B has a rectangular main body 1031a, a first pair of legs 1031b and 1031c located on a first surface 1031a-1 of the main body 1031a and a second pair of legs 1031d and 1031e located on a second surface 1031a-2 of the main body 1031a opposite to the first surface 1031a-1. The first pair of legs 1031b and 1031c extends from a first edge E1 of the first surface 1031a-1 along a direction D1 perpendicular to the first surface 1031a-1, and the second pair of legs 1031d and 1031e extends from a second edge E2 of the second surface 1031a-2 along a direction D2 perpendicular to the second surface 1031a-2. The directions D1 and D2 are opposite to each other. The first and second edges E1 and E2 are perpendicular to each other. The first and second T-shaped parts 1032B and 1033B are respectively attached to the first and second surfaces 1031a-1, 1031a-2 of the main body 1031a. Each of the first T-shaped part 1032B and second T-shaped part 1033B has two arms arranged orthogonally and connected to each other. Accordingly, each of the first T-shaped part 1032B and second T-shaped part 1033B has a first arm with two ends connected to the leaf springs and a second arm having a free end as shown in FIG. 3A and FIG. 3B.

The first pair of leaf springs include a first leaf spring 1034B and a second leaf spring 1035B, which are arranged to extend along first parallel planes in a first direction X. The first leaf spring 1034B is attached to a side surface of the first leg 1031b and a first end 1032B-1 of the first arm of the first T-shaped part 1032B. The second leaf spring 1035B is attached to a side surface of the second leg 1031c and a second end 1032B-2 of the first arm of the first T-shaped part 1032B. The free end 1032B-3 of the second arm of the first T-shaped part 1032B is received by a space formed between the first pair of legs 1031b and 1031c. The width of the free end 1032B-3 is slightly smaller than the distance between the first pair of legs 1031b and 1031c.

Similarly, the second pair of leaf springs include a third leaf spring 1036B and a fourth leaf spring 1037B, which are arranged to extend along second parallel planes in a second direction Y perpendicular to the first direction X. The third leaf spring 1036B is attached to a side surface of the third leg 1031d and a first end 1033B-1 of a first arm of the second T-shaped part 1033B. The fourth leaf spring 1037B is attached to a side surface of the fourth leg 1031e and a second end 1033B-2 of the first arm of the second T-shaped part 1033B. The free end 1033B-3 of the second arm of the second T-shaped part 1033B is received by a space formed between the second pair of legs 1031e and 1031d. The width of the free end 1033B-3 is slightly smaller than the distance between the second pair of legs 1031d and 1031e.

In use, the first T-shaped part 1032B of the compliant structure 103B may be coupled to the bonding tool gripper 102 and the first pair of leaf springs 1034B and 1035B may be arranged extending along a direction parallel to the extension direction D of the bonding tool gripper 102. The second T-shaped part 1033B is connected to the frame 101. Accordingly, the second pair of leaf springs 1036B and 1037B are positioned extending along a direction perpendicular to the extension direction D of the bonding tool gripper 102. Thus, in this double-layer compliant structure 103B, the first pair of leaf springs 1034B and 1035B are positioned nearer the bonding tool gripper 102. These leaf springs are configured to deform or deflect in response to a reaction force exerted by the bonding tool gripper 102 in a direction perpendicular to its extension. This reaction force is caused by a misalignment between the bonding tool 20 and the retaining hole 211 during insertion. The second pair of leaf springs 1036B and 1037B are located above the first pair of leaf springs 1034B and 1035B and are configured to deform in response to a reaction force experienced from the bonding tool gripper 102 in a direction parallel to its extension. This reaction force is also caused by a misalignment between the bonding tool 20 and the retaining hole 211 during insertion.

The compliant structure 103A, as shown in FIG. 2A and FIG. 2B, is an integrally formed resilient structure, making it easy to install on other components of the bonding tool replacement device 100. In contrast, the compliant structure 103B, as shown in FIG. 3A and FIG. 3B, is assembled from multiple independent parts, which allows for the replacement of damaged parts individually. Additionally, the design of the compliant structure 103A has a smaller size in the Z direction, while the design of the compliant structure 103B has a smaller size in the XY plane. Therefore, these two designs can be used in different scenarios to meet different space requirements.

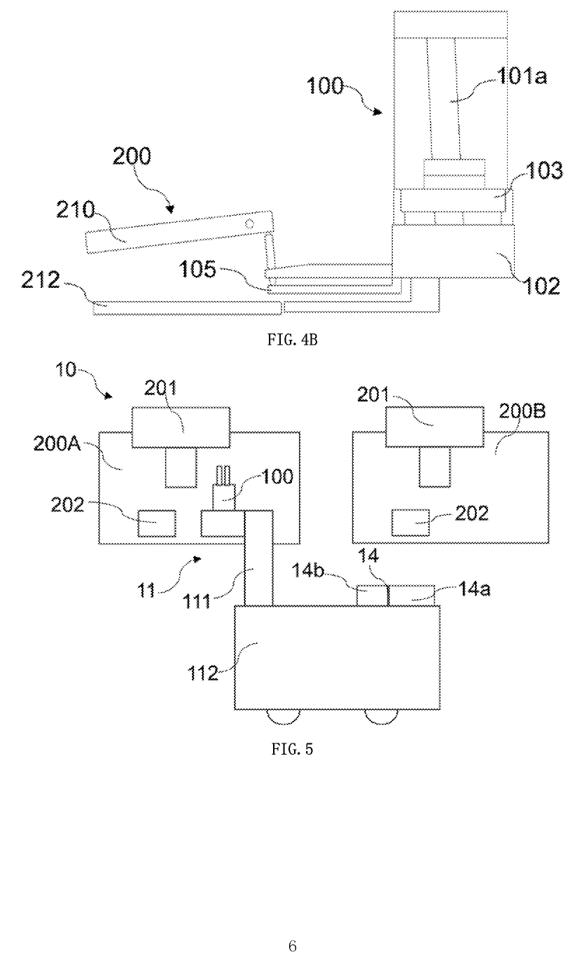

FIG. 4A and FIG. 4B respectively show perspective and side views of the bonding tool replacement device 100 that further includes a holding structure 105 according to some embodiments of the invention. Referring to FIG. 4A and FIG. 4B, the holding structure 105 is connected to the bonding tool gripper 102 at a position directly below the bonding tool gripper 102. It is configured to support or hold a tip portion of a bonding tool 20 held by the bonding tool gripper 102. The holding structure 105 may include a narrowing receiving hole for holding the tip portion of the bonding tool 20. This holding structure 105 is used for holding the tip portion of the bonding tool 20 when the bonding tool gripper 102 releases the bonding tool 20 and forms a guide hole for inserting the bonding tool 20 into the retaining hole 211 of the bonding tool retainer 210. The holding structure 105 is provided for temporarily supporting or holding the bonding tool 20 so that the misalignment between the bonding tool 20 and the retaining hole 211 is not too large to be compensated for by the compliant structure 103.

FIG. 5 is a schematic diagram illustrating a wire bonding system 10 including a plurality of wire bonding apparatus and a bonding tool replacement apparatus 11 according to some embodiments of the invention. As shown in FIG. 5, the wire bonding system 10 includes two wire bonding apparatus 200A and 200B, and a bonding tool replacement apparatus 11. The bonding tool replacement apparatus 11 includes a bonding tool replacement device 100 and a movable manipulator configured and operative to transfer the bonding tool replacement device 100 between a standby position and the operation position associated with each of the wire bonding apparatus 200A or 200B.

Referring to FIG. 5, the movable manipulator includes an automated vehicle 112 and a robot arm 111 movably installed on the automated vehicle 112. The bonding tool replacement device 100 is carried by the robot arm 111. Specifically, the frame 101 of the bonding tool replacement device 100 may be coupled to the robot arm 111 such that the bonding tool replacement device 100 together with the robot arm 111 is moved by the automated vehicle 112 between the standby position and the operation position. Specifically, as shown in FIG. 1A to FIG. 1D, at the operation position associated with a wire bonding apparatus, the bonding tool gripper 102 of the bonding tool replacement device 100 is positioned between a bonding tool retainer 210 and a Cu Kit 212 of the wire bonding apparatus.

Each wire bonding apparatus 200A or 200 B includes a bond head 201 configured for wire bonding and a first docking station 202. The frame 101 of the bonding tool replacement device 100 may include a first connecting component configured to detachably connect the frame 101 to the first docking station 202 for stabilizing the frame 101 when the bonding tool gripper 102 is inserting a bonding tool into the wire bonding apparatus 200A or 200B. In one embodiment, the first connecting component may include a plurality of first locking elements and the first docking station 202 may include a plurality of second locking elements. The first and second locking elements are shaped and sized to detachably connect with one another to mount the frame 101 on the first docking station 202. Additionally, the first docking station 202 may incorporate a solenoid to automatically control the locking and release mechanism between the first docking station 202 and the bonding tool replacement device 100.

On the automated vehicle 112, a container 14 for holding bonding tools may be provided. The container 14 may include a first holder or storage 14a for receiving or holding used bonding tools and a second holder or storage 14b for holding new bonding tools. The robot arm 111 is also configured to move the bonding tool replacement device 100 between the operation position and the bonding tool container, wherein the bonding tool gripper 102 of the bonding tool replacement device 100 is further configured to pick up a new bonding tool from the container 14 or return a used bonding tool to the container 14. The first holder 14a and the second holder 14b may comprise two parts of a single container or two separate containers.

A second docking station (not shown) may be provided on the automated vehicle 112. The first connecting component is further configured to detachably connect the frame 101 to the second docking station for stabilizing the frame 101 when the bonding tool gripper 102 is picking up a new bonding tool from the container 14 or returning a used bonding tool to the container 14. Similar to the first docking station 202, the second docking station may include a plurality of locking elements which are shaped and sized to detachably connect with the plurality of first locking elements of the first connecting component when the second docking station is engaged by the frame 101.

Alternatively, the second connecting component and the first connecting component may be two separate components. The second connecting component may include a plurality of third locking elements located on the frame 101, shaped and sized to connect detachably with a plurality of fourth locking elements located on the second docking station.

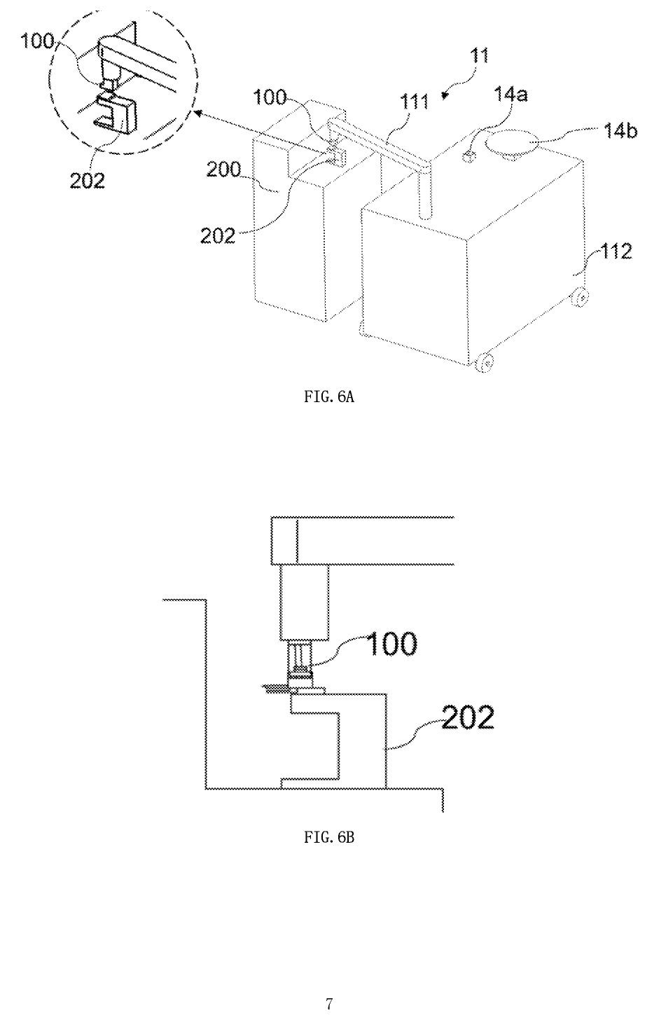

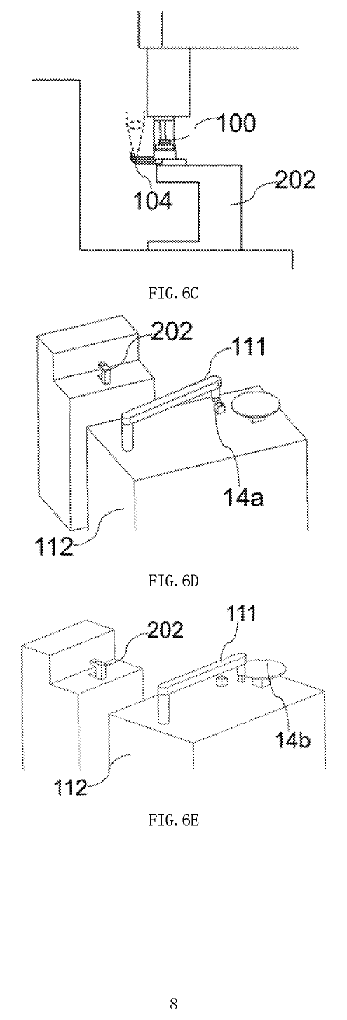

FIG. 6A to FIG. 6E illustrate some steps of a bonding tool replacement method for a wire bonding apparatus 200 using the bonding tool replacement apparatus 11 according to some embodiments of the invention. In these embodiments, the bonding tools are in the form of capillaries.

In Step 601, referring to FIG. 6A, the automated vehicle 112 transfers the bonding tool replacement device 100 installed on the robot arm 111 from a standby position to an operation position associated with the wire bonding apparatus 200.

The automated vehicle 112 may be configured to transfer the bonding tool replacement device 100 upon receipt of a bonding tool replacement signal from the wire bonding apparatus 200 or a server (not shown) communicably connected to the wire bonding apparatus 200. The bonding tool replacement signal may be generated by the wire bonding apparatus 200 itself or the server based on the usage information of the bonding tool received from the wire bonding apparatus 200. As shown in FIG. 6A, the bonding tool replacement device 100 is transferred to a position above the first docking station 202 such that the bonding tool replacement device 100 can be detachably connected to the first docking station 202.

In Step 602, A camera installed on the robot arm 111 inspects a fiducial mark located on the first docking station 202 to determine a position of the first docking station 202.

As a vision system of the bonding tool replacement apparatus 11, the camera is configured to detect the fiducial mark located on the first docking station 202 for aligning the frame 101 with the first docking station 202 prior to engagement between the first docking station 202 and the frame 101.

In Step 603, The robot arm 111 moves the bonding tool replacement device 100 according to the determined position of the first docking station 202 to connect the frame 101 of the bonding tool replacement device 100 to the first docking station 202. Referring to FIG. 6B, the bonding tool replacement device 100 is coupled to the top surface of the first docking station 202.

In Step 604, referring to FIG. 6C, a camera installed on the wire bonding apparatus 200 inspects a position indicator 104 of the bonding tool replacement device 100 to determine a position of the bonding tool gripper 102 based on a predetermined positional relationship between the position indicator 104 and the bonding tool gripper 102. In this step, the position of the bonding tool gripper 102 may refer to the receiving hole of the bonding tool gripper 102.

In Step 605, the wire bonding apparatus 200 with a used bonding tool 20’ moves to a position above the bonding tool gripper 102 according to the determined position of the bonding tool gripper 102. The bonding tool retainer 210 of the wire bonding apparatus 200 is raised and positioned at an oblique angle relative to a horizontal plane or direction. The tilt angle of the bonding tool retainer 210 is consistent with the tilt angle of the sliding track or column 101a so that the bonding tool gripper 102 is operable to grip the used bonding tool 20’ and remove it from the retaining hole 211 of the bonding tool retainer 210.

In Step 606, the bonding tool gripper 102 is actuated and operated to grip the used bonding tool 20’ and remove it from the bonding tool retainer 210. The wire bonding apparatus 200 may move back to its operation position for wire bonding or its standby position after the used bonding tool 20’ is removed from it.

In Step 607, after the bonding tool replacement device 100 grips the used bonding tool 20’, it is released from the first docking station 202.

In Step 608, referring to FIG. 6D, the robot arm 111 transfers the bonding tool replacement device 100 to a position above the first holder 14a on the automated vehicle 112, and then the bonding tool gripper 102 is operated to release the used bonding tool 20’ and place it onto the first holder 14a.

In Step 609, referring to FIG. 6E, the robot arm 111 transfers the bonding tool replacement device 100 to a position above the second holder 14b, and then the bonding tool gripper 102 is actuated to grip a new bonding tool 20 and pick it up from the second holder 14b.

In Step 610, the robot arm 111 transfers the bonding tool replacement device 100 with the new bonding tool 20 back to the operation position associated with the wire bonding apparatus 200.

In Step 611, the camera installed on the robot arm 111 inspects the fiducial mark on the first docking station 202 to determine the position of the first docking station 202 and the bonding tool replacement device 100 is coupled to the first docking station 202 based on the determined position of the first docking station 202.

In Step 612, the camera installed on the wire bonding apparatus 200 inspects the position indicator 104 of the bonding tool replacement device 100 to determine the position of the bonding tool gripper 102 and the new bonding tool 20 gripped by the bonding tool gripper 102 based on a predetermined positional relationship between the position indicator 104 and the bonding tool gripper 102.

In Step 613, the bonding tool retainer 210 of the wire bonding apparatus 200 is moved to a position above the bonding tool gripper 102 with a predetermined tilt angle relative to the horizontal plane based on the predetermined position of the bonding tool gripper 102 and the new bonding tool 20. The bonding tool gripper 102 is positioned between the bonding tool retainer 210 and the Cu Kit 104.

In Step 614, the bonding tool gripper 102 is moved along the sliding track or column 101a until the new bonding tool 20 is received by the retaining hole 211. If the retaining hole 211 includes a chamfered receiving portion, the new bonding tool 20 is first received by the chamfered receiving portion of the retaining hole 211. If there is a misalignment between the central axis of the new bonding tool 20 and that of the retaining hole 211, the compliant structure 103 deforms or deflects in response to the misalignment, thereby adjusting the position and angle of the new bonding tool 20 to align it with the retaining hole 211 during the insertion of the new bonding tool 20. In other words, the deformation of the compliant structure 103 allows the new bonding tool 20 to deflect into alignment with the retaining hole 211 during insertion when the new bonding tool 20 and the retaining hole 211 are misaligned.

The bonding tool replacement device 100 may further include a holding structure 105 positioned directly below the bonding tool gripper 102. The holding structure 105 may include a receiving hole shaped and sized to receive the tip portion of the new bonding tool 20. During the insertion of the new bonding tool 20, when the misalignment between the central axis of the new bonding tool 20 and that of the retaining hole 211 is larger than the adjustment scope of the compliant structure 103, the bonding tool gripper 102 may move the new bonding tool 20 to allow the tip portion thereof to be held by the holding structure 105, and then release the new bonding tool 20 such that the bonding tool gripper 102 becomes a guide hole for inserting the new bonding tool 20 into the retaining hole 211 of the bonding tool retainer 210. In this scenario, the holding structure 105 is connected to the bonding tool gripper 102 such that the compliant structure 103 is deflected to compensate for or absorb the misalignment between the new bonding tool 20 and the retaining hole 211 when necessary.

In Step 615, after the new bonding tool 20 is inserted into the bonding tool retainer 210, the bonding tool gripper 102 moves to an open configuration to allow the wire bonding apparatus 200 to move back to its operation position for wire bonding. Then, the bonding tool replacement device 100 is decoupled from the first docking station 202 and moved back to its standby position on the automated vehicle 112.

If a second docking station is provided on the automated vehicle 112, before the bonding tool gripper 102 is operated to release and place the used bonding tool 20’ onto the first holder 14a, the bonding tool replacement device 100 may be moved by the robot arm 111 such that the frame 101 is connected to the second docking station for stabilizing the frame 101 when the bonding tool gripper 102 is returning the used bonding tool 20’ to the first holder 14a and picking up the new bonding tool 20 from the second holder 14b. The camera installed on the robot arm 111 may be further configured to inspect a fiducial mark on the second docking station for aligning the frame 101 with the second docking station prior to engagement between the second docking station and the frame 101. Specifically, the camera is used to determine the position of the second docking station and the bonding tool replacement device 100 is coupled to the second docking station based on the determined position. The frame 101 is released from the second docking station after the new bonding tool 20 is picked up.

Alternatively, the frame 101 may be connected to the second docking station after the used bonding tool 20’ is returned to the first holder 14a. That is to say, the second docking station may be provided only for stabilizing the frame 101 when the bonding tool gripper 102 is picking up the new bonding tool 20 from the second holder 14b.

The use of a compliant structure in the bonding tool replacement device enables automatic alignment between the bonding tool and the bonding tool retaining hole, enhancing the efficiency and precision of the bonding tool replacement process and, consequently improving the productivity of the wire bonding apparatus. Additionally, the complaint structure has a simple design and is easy to manufacture, which can significantly reduce equipment costs and greatly extend its lifespan. Moreover, the bonding tool replacement apparatus can replace a bonding tool as needed based on signals generated by the wire bonding apparatus or a server in communication with the wire bonding apparatus. This effectively eliminates the inefficiencies and operational errors associated with manual replacement.

Although the present invention has been described in considerable detail with reference to certain embodiments, other embodiments are possible. For example, the method provided by embodiment of the invention may also be used for forming vertical wire interconnects by other bonding approaches. Accordingly, the wire bond formed by the wire bonding apparatus may include a wire bonding tool for forming other types of wire bonds formed on the bonding pad. Therefore, the spirit and scope of the appended claims should not be limited to the description of the embodiments contained herein.

1. A bonding tool replacement apparatus for inserting a bonding tool into a retaining hole of a bonding tool retainer of a wire bonding apparatus, the bonding tool replacement apparatus comprising:
a frame,
a bonding tool gripper supported by the frame, the bonding tool gripper being configured to grip the bonding tool and to insert the bonding tool into the retaining hole at an operation position associated with the wire bonding apparatus by moving the bonding tool toward the retaining hole, and
a compliant structure flexibly coupling the bonding tool gripper to the frame to enable relative movement of the bonding tool gripper with respect to the frame, wherein the compliant structure is configured to deform in response to misalignment between the bonding tool gripped by the bonding tool gripper and the retaining hole during insertion to allow the bonding tool to deflect into alignment with the retaining hole during insertion when the bonding tool and retaining hole are misaligned.

2. The bonding tool replacement apparatus according to claim 1, wherein the bonding tool gripper is further configured to grip a used bonding tool retained by the wire bonding apparatus at the operation position and to remove it from the wire bonding apparatus.

3. The bonding tool replacement apparatus according to claim 1, wherein the compliant structure comprises resilient components that are arranged to flex in response to a positional or angular offset of a central axis of the bonding tool relative to that of the retaining hole so as to allow the bonding tool to deflect into alignment with the retaining hole while the bonding tool is being inserted into the retaining hole.

4. The bonding tool replacement apparatus according to claim 3, wherein the compliant structure comprises a first pair of leaf springs arranged to extend along first parallel planes that are parallel to an extension direction of the bonding tool gripper.

5. The bonding tool replacement apparatus according to claim 4, wherein the compliant structure further comprises a second pair of leaf springs arranged to extend along second parallel planes that are orthogonal with the extension direction of the bonding tool gripper.

6. The bonding tool replacement apparatus according to claim 1, further comprising a position indicator fixedly located with respect to the bonding tool gripper for determining a position of the bonding tool gripper with a vision system.

7. The bonding tool replacement apparatus according to claim 6, wherein the position indicator is located on an arm coupled to the bonding tool gripper such that the position indicator is viewable by the vision system when the bonding tool replacement device is located at the operation position associated with the wire bonding apparatus, wherein the vision system includes a camera installed on the wire bonding apparatus.

8. The bonding tool replacement apparatus according to claim 1, further comprising a holding structure connected to the bonding tool gripper at a position directly below the bonding tool gripper, wherein the holding structure is configured to support a tip portion of the bonding tool during the insertion of the bonding tool into the retaining hole.

9. The bonding tool replacement apparatus according to claim 8, wherein the bonding tool gripper is further configured to release the bonding tool to form a guide hole for inserting the bonding tool into the retaining hole when the tip portion of the bonding tool is held by the holding structure.

10. The bonding tool replacement apparatus according to claim 1, further comprising a first connecting component configured to detachably connect the frame to a first docking station of the wire bonding apparatus for stabilizing the frame when the bonding tool gripper is inserting the bonding tool into the wire bonding apparatus.

11. The bonding tool replacement apparatus according to claim 10, wherein the first connecting component includes a plurality of first locking elements provided on the frame, which are shaped and sized to detachably connect with a plurality of second locking elements of the first docking station when the first docking station is engaged by the frame.

12. The bonding tool replacement apparatus according to claim 10, further comprising a vision system configured to detect a fiducial mark located on the first docking station for aligning the frame with the first docking station prior to engagement between the first docking station and the frame.

13. The bonding tool replacement apparatus according to claim 1, further comprising a movable manipulator operative to transfer the bonding tool gripper between a standby position and the operation position associated with the wire bonding apparatus.

14. The bonding tool replacement apparatus according to claim 13, wherein the movable manipulator includes an automated vehicle and a robot arm movably installed on the automated vehicle, wherein the frame is installed on the robot arm.

15. The bonding tool replacement apparatus according to claim 14, further comprising a bonding tool container configured to hold at least one bonding tool, wherein the robot arm is further configured and operative to move the bonding tool gripper between the operation position associated with the wire bonding apparatus and the bonding tool container, and wherein the bonding tool gripper is configured to pick up the bonding tool from the container or return a used bonding tool to the container.

16. The bonding tool replacement apparatus according to claim 15, further comprising a second connecting component configured to detachably connect the frame to a second docking station for stabilizing the frame when the bonding tool gripper is picking up the bonding tool from the container or returning the used bonding tool to the container.

17. The bonding tool replacement apparatus according to claim 14, wherein the movable manipulator is configured to transfer the bonding tool gripper to the operation position of the wire bonding apparatus upon receipt of a bonding tool replacement signal associated with the wire bonding apparatus.

18. The bonding tool replacement apparatus according to claim 14, wherein the movable manipulator is further configured to receive the bonding tool replacement signal that is generated according to preset conditions from the wire bonding apparatus or a server communicably connected to the movable manipulator and the wire bonding apparatus.

19. The bonding tool replacement apparatus according to claim 1, wherein when inserting the bonding tool into the retaining hole, the bonding tool gripper is positioned between the wire bonding apparatus and a copper wire bonding kit used in association with the wire bonding apparatus.

20. The bonding tool replacement apparatus according to claim 1, wherein the bonding tool gripper is configured to grip the bonding tool such that a central axis of the bonding tool is substantially aligned with that of the retaining hole when the bonding tool retainer is raised and positioned at an oblique angle relative to a horizontal plane, and the bonding tool gripper is further configured to move along a direction substantially parallel to the central axis of the retaining hole so as to insert the bonding tool into the retaining hole.

21. A method for inserting a bonding tool into a retaining hole of a bonding tool retainer of a wire bonding apparatus, wherein the method comprises:
positioning a bonding tool replacement apparatus at an operation position associated with the wire bonding apparatus, wherein the bonding tool replacement apparatus includes a frame, a bonding tool gripper and a compliant structure flexibly coupling the bonding tool gripper to the frame to enable relative movement of the bonding tool gripper with respect to the frame; and
gripping the bonding tool with the bonding tool gripper and moving the bonding tool toward the retaining hole to insert the bonding tool into the retaining hole with the bonding tool gripper, wherein during the insertion of the bonding tool, the compliant structure is deformable in response to misalignment between the bonding tool and the retaining hole to allow the bonding tool to deflect into alignment with the retaining hole during insertion when the bonding tool and retaining hole are misaligned.
